(19) United States
(12) Patent Application Publication
(10) Pub. No.: US 2026/0244108 A1
(43) Pub. Date: Aug. 20, 2026

(54) A PHOTOLITHOGRAPHY METHOD AND SYSTEM

(71) Applicant: ISTANBUL MEDIPOL UNIVERSITESI, Istanbul (TR)

(72) Inventors: Muhammed Fatih TOY, Istanbul (TR); Tolga GÜRCAN, Istanbul (TR)

(21) Appl. No.: 19/483,807

(22) PCT Filed: Mar. 6, 2023
(86) PCT No.: PCT/TR2023/050216

§ 371 Date: Nov. 12, 2025

(30) Foreign Application Priority Data
Mar. 7, 2022 (TR) 2022/003354
Jul. 8, 2022 (TR) 2022/011299

(51) Int. Cl. G03F 7/00

(52) U.S. Cl. CPC G03F 7/70291; G03F 7/70508; G03F 7/70516

(57) ABSTRACT

A photolithography method comprising the steps of: providing a target phase, transmitting a beam from an EM radiation source to a spatial light modulator and the beam reflected from the spatial light modulator to a sample, dividing a beam provided by a light source into two as an object wave and a reference wave and transmitting the object wave to the sample, merging and sending the object wave through the sample and the reference wave to an image receiving element and obtaining a phase image, comparing the phase image and the target phase and the quantizing the phase image to create a new image for the spatial light modulator, if a difference between the phase image and the target phase is above a predetermined value.

### TECHNICAL FIELD

The invention is related to a photolithography method based on curing by EM radiation source for production of optical means and a system.

### PRIOR ART

In photolithography method, a light, preferably an UV light is transmitted through mask to a photoresist which is sensitive to light in that wavelength and desired shapes are formed on surface by shape of the mask, specification of the photoresist and a chemical process.

A maskless photolithography is used for an alternative said method. In this method, the light is sent to a spatial light modulator, as known as SLM, and the light reflected from SLM provides an output, according to the target shape stored in the SLM.

A grayscale photolithography has become a powerful tool in the fabrication of micro-optical elements. Traditional photolithography applies same photoresist does through whole area which results in 2-D structures. Grayscale lithography varies the applied does and after a development process end up with 3-D structures.

Grayscale lithography can be used for production microfluidic channels¹, lenses², optic fibers³, gratings and semi-conductor devices. In the production method designed as an open loop, multiple parameters must be optimized to improve features of the targeted product and the production must be carried out in ideal environment.

A tight dimensional necessity in this method requires pre-calibration on the sample. The pre-calibration is repeated until error margins fall below the desired tolerances. Also, once the calibration is completed, the environmental conditions should not change to not affect the system as system is inherently susceptible to environmental effects.

In known state of the art, the products are characterized only after the production and the separate devices are used for production and characterization. By looking at the difference between the characterization result and the targeted phase, the parameters used in production are optimized. For this reason, both the production process is prolonged for different types of elements and the cost increases. In addition, environmental factors are controlled in order to minimize possible variations in production, and the optical linearity (magnification, distortion, vignetting, etc.) in the production device is tried to be at the best level. Taking all these parameters under control increases the complexity and cost of the systems.

There are some optical characterization techniques such as spectroscopic ellipsometry⁴, phase sensitive ellipsometry⁵, laser reflectometry⁶, multi-beam interferometry⁷, and emission spectroscopy⁸ which checks the requirement for non-destructive testing but is generally used for single point measurements. These techniques might be adequate for planar shapes but are insufficient in providing necessary feedback information to produce complex phase plates. To fully correct any deviation in the field of view, an imaging method rather than a single point method is preferred. For this job quantitative phase imaging stands out with its good performance in noisy environments. The phase of sample can be obtained by the reconstruction of digitally recorded holograms in digital holographic microscopy⁹ or by various quantitative phase microscopy methods^{10,11,12}. There are some preliminary works which utilizes real time quantitative phase imaging, but their use is mainly limited in the finding the varying etching rates.

U.S. Pat. No. 5,076,974A discloses a curing method for partially polymerize sample. The curing is carried out by EM radiation in this disclosure. A photoresist calibration and final characterization is required for this method.

U.S. Pat. No. 9,229,330B2 discloses a method for pattern writing in nanoscale. Herein, beams which are the first and the second wavelength are sent to sample and after that, a portion of the photons of a second wavelength that are reflected after passing through said sample material is detected.

In KR100864391B1, a beam provided from a light source is transmitted to a SLM via a beam splitter and the beam reflected from the beam splitter reflects to a sample. Herein, a rasterizer that is continuously feed data to the SLM is used.

As a result, all of the problem mentioned above has made it necessary to provide a novelty in the related field.

### BRIEF DESCRIPTION AND OBJECTS OF THE INVENTION

The main object of the present invention is to establish a photolithography method structure for the production of polymerization-based optics with instantaneous calibration. Accordingly, the method comprises steps of

providing a target phase,

transmitting a beam from an EM radiation source to a spatial light modulator and the beam reflected from the spatial light modulator to a sample,

dividing a beam provided by a light source into two as a reference wave and an object wave and transmitting the object wave to the sample,

merging and sending the object wave went through the sample and the reference wave to an image receiving element and obtaining a phase image,

comparing the phase image and the target phase and the quantizing the phase image to create a new image for the spatial light modulator, if a difference between the phase image and the target phase is above a predetermined value.

Thus, the desired pattern of the process is created by intervening instantly by means of the phase delay measurements coming from the digital imaging section of the system and measuring how phase of each point evolves in time and correcting the deviations, and accordingly, the requirement for pre-calibration and post-characterization of the photoresist is eliminated.

In a preferred embodiment of invention, the quantization is carried out by a formula of

$${W}_{k} ( x , y ) = \{ \begin{matrix}{2}^{n} − 1 , if {Δ φ}_{k} ( x , y ) > π \\ \frac{( {2}^{n} − 1 ) ⋆ Δ {φ}_{k} ( x , y )}{π} , else\end{matrix} or {W}_{k} ( x , y ) = \{ \begin{matrix}{2}^{n} − 1 , if {Δ φ}_{k} ( x , y ) > a \\ ( {2}^{n} − 1 ) ⋆ {[ \frac{{Δ φ}_{k} ( x , y )}{a} ]}^{m} , else\end{matrix}$$

wherein, Wₖ is the quantized grayscale image to be projected on the spatial light modulator, Δφₖ is the phase difference between the target phase and the present measurement, n is the bit depth of the spatial light modulator x and y is coordinates of the pixels and k is the iteration number. In the generalized form of the equation, a and m are coefficients.

In a preferred embodiment of invention, the reference wave is angularly transmitted to the image receiving element and that enables to utilize off-axis digital holography methods for determining phase in the sample.

In a preferred embodiment of invention, one of the reference wave and the object wave is delayed before the merging. Thus, temporal phase of the reference wave and the object wave is matched.

In a preferred embodiment of invention, the object wave and EM radiation beam are sent in same axis to the sample and a dichroic mirror selected to enables passing of the object wave and to reflects the EM radiation beam to the sample is positioned in said axis. Thus, both operations can be performed on a single axis and the system becomes advantageous about volume to be used.

The main object of the present invention is to establish a photolithography system structure for the production of polymerization-based optics with instantaneous calibration. Accordingly, the system comprises,

an EM radiation source and a spatial light modulator for receiving a beam from the EM radiation source and reflecting the received beam.

a light source and a beam splitter for dividing a beam provided by the light source into two as a reference wave and an object wave which is transmitted the object wave to the sample,

a beam splitter for merging the reference wave and the object wave,

an image receiving element for receiving merged the reference wave and the object wave,

a processor unit having

a memory element for storing a target phase and a phase image received by the image receiving element,

a processing element is configured to determine the phase image and the target phase and to compare the phase image and the target phase according to a predetermined value and to quantize the difference for creating a new image and to send the new image to the spatial light modulator.

### DESCRIPTION OF THE FIGURES OF THE INVENTION

The figures and related descriptions necessary for the subject matter of the invention to be understood better are given below.

FIG. 1. A representative schematic view of the subject matter of the invention.

FIG. 1a. An exemplary target phase image.

FIG. 1b. Reconstructed images that are obtained by reconstruction of the target phase image of FIG. 1a in iterations k=1, 46, 75.

FIG. 1c. New images for the spatial light modulator are obtained as a result of quantization in the system for the target phase of FIG. 1a in iterations k=1, 46, 75.

FIG. 2. An exemplary schematic view of the experimental installation.

FIG. 3. An exemplary target phase image.

FIG. 3a. A result image is obtained by the system of the prior art.

FIG. 3b. A result image is obtained by the subject matter of the invention.

FIG. 3c. Phase profiles of the images shown in FIG. 3-3b.

FIG. 4. Another exemplary target phase image

FIG. 4a. A result image of FIG. 4 is obtained by the system of the prior art.

FIG. 4b. A result image of FIG. 4 is obtained by the subject matter of the invention.

FIG. 4c. Phase profiles of the images shown in FIG. 4-4b.

FIG. 5. An exemplary target phase image for a vortex phase plate.

FIG. 5a. A result image of FIG. 5 is obtained by the system of the prior art.

FIG. 5b. Phase profiles of the images shown in FIG. 5-5a.

FIG. 6. Physically observed output beam from the fabricated vortex phase plate.

FIG. 6a. Numerical calculation of the output beam from the final complex field attained from the sample.

FIG. 6b. A vertical and horizontal profile comparisons of FIG. 6 and FIG. 6a.

### REFERENCE NUMBERS

The parts and components are given in the figures are referenced for the subject matter of the invention to be understood better.
1. Image receiving element
2. Beam splitter
3. Spatial light modulator
4. Mirror
5. Sample
6. Lenses
7. Object wave
8. Reference wave
9. EM radiation source
10. Light source
11. Diffuser
12. Spatial filter
13. Prism

### DETAILED DESCRIPTION OF THE INVENTION

The invention is related to a photolithography method based on curing by EM radiation source for production of optical means and a system.

The photolithography method described in detailed description is disclosed for producing articles, especially optics, based on polymerization. However, it is possible to extend the technique to non-polymerization-based materials. Photoresists (including photopolymers where the solubility of the material changes with light exposure) in general are usable. Additionally, photoinduced selective etching or deposition of glasses, crystals or metals would be compatible with the method as well. With a suitable spatial light modulator (2) or scanning system ultrafast (femtosecond) laser etching of metals, crystals, glasses or ultrafast laser induced refractive index change in crystals and glasses will be other alternative use scenarios. For the uses with a reflective sample, the system is required to be modified for reflection imaging geometry. However, the approach and the method will stay the same.

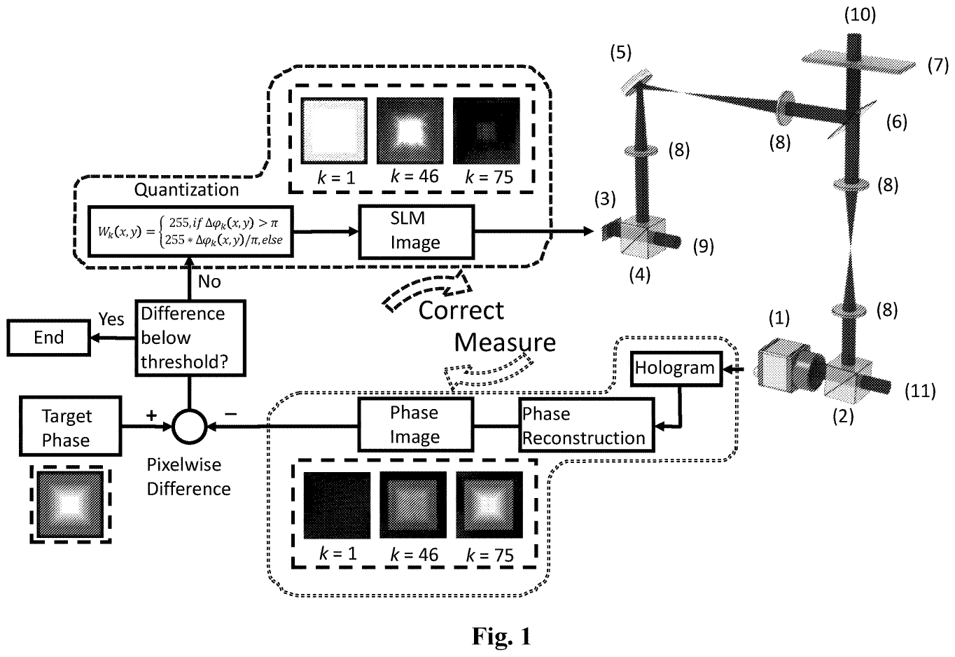

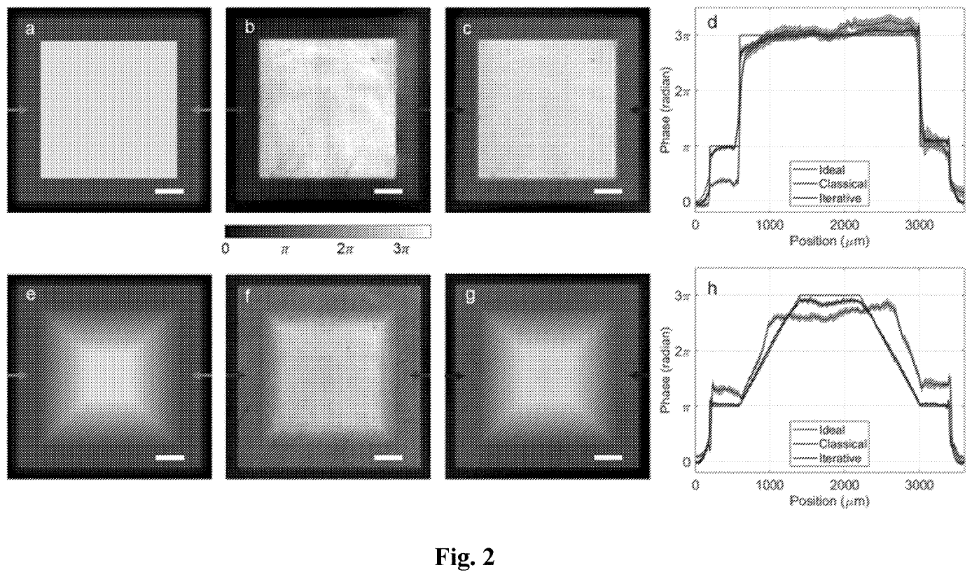

Referring to FIGS. 1 and 2; the subject matter of the invention comprises two parts. These are photolithography part and processing part.

For the photolithography process, a target phase, for example image shown in FIG. 1a, is provided. The target phase can be given as an image or described mathematically. The target phase is transferred to a memory unit, especially memory element of a processing unit. The processing unit comprises a processing element, as will be described later.

In the beginning of the photolithography process, a EM radiation source is started and an EM radiation beam is transmitted to a spatial light modulator (3) and reflected from the spatial light modulator (3) to a sample (5). Herein, EM radiation source (9) is selected in such a way that wavelength of the it is between 260-410 nm, especially 405 nm. Preferably, the EM radiation source (9) is an UV light source or a green light source with wavelength of 500 nm-540 nm. Preferably, the EM radiation source (9) is selected in such a way that the beam of the EM radiation source (9) filling at least all the active surface of the spatial light modulator (3), especially overfills the active surface of the spatial light modulator (3).

The EM radiation beams can be directly transferred from the spatial light modulator (3) to the sample (5) or preferably, reflected by mirrors to the sample (5). In the embodiment shown in FIGS. 1 and 2, the EM radiation beam is transmitted to the sample (5) by the mirrors (4) positioned in angled way in respect to direction of the beam. Preferably, these mirrors (4) are positioned at an angle of 45° with respect to direction of the beam. Lenses (6) may be positioned between the mirrors (4).

Preferably, a beam splitter (2) is positioned in front of the spatial light modulator (3). Said spatial light modulator (3) is a polarizing spatial light modulator (3), as known as PBS. The PBS crates contrast for the EM radiation beam.

In a preferred embodiment, a diffuser (11), preferably rotational diffuser (11), is positioned between the beam splitter (2) and the EM radiation source (9). The diffuser (11) reduces effect of speckles caused by the laser beam. In addition to that, planarly provided another diffuser (11) can be positioned the spatial light modulator (3) and the EM radiation source (9).

When the EM radiation beam contact the sample (5), the patterning/writing process begins. The EM radiation source (9) may continuously transmit beam or stops after while and other light source (10) starts. For the present system, each loop of the iteration has a EM radiation beam duration of 50 ms. Convergence is reached typically after 125 iterations. This duration may be longer or shorter depending on the intensity of the EM radiation source. Hence it is possible to say that typically EM radiation exposure is expected to be less than few hundred milliseconds (20-200 ms) with few hundred iterations (100-400).

Said second light source (10) is preferably coherent laser beam. The light source (10) radiates the beam having wavelength that does not cause polymerization on the sample (5). The wavelength of the beam can be higher than 440 nm, preferably 660 nm, for polymer which is sensitive to 405 nm. Herein, some margin of absorption must be accounted, too.

The beam radiated from the light source (10) is divided by a beam splitter (2). Said beam splitter (2) is non-polarizing. One of two part of the divided beam can be named as an object wave (7) and another one is named as a reference wave (8). The beam transmitted by the light source (10) passes through to a spatial filter (12) to ensure full spatial coherence, before reaching the beam splitter (2).

The object wave (7) passes through the sample (5). The beam splitter (2) can be positioned to reflect the object wave (7) directly on the surface of the sample (5). Alternatively, even if the beam splitter (2) does not guide the object wave (7) directly to the sample (5), the object wave (7) can be guided to the sample (5) by another beam splitter (2) and/or prism (13) and/or the mirrors (4).

The object wave (7) is merged with the refence wave (8) by a beam splitter, after the object wave (7) passes through the sample (5). The object wave (7) and the reference wave (8) go into different surfaces of the beam splitter (2) and go out from same surface of the beam splitter (2). The mirrors (4) can be used for guiding the object wave (7) and/or the reference wave (8) to ensure they go into the surface of the beam splitter (2).

To ensure match the temporal phase of the object wave (7) and the reference wave (8), one of the waves, preferably the object wave make pass from a delay line. The delay line is a beam path where beam splitter (2) and/or prisms (13) and/or mirrors (4) is positioned onto the path to make way of the beam longer. Preferably, the delay line includes knife edge mirror (4) and right-angled prism (13).

In a preferred embodiment of the invention, EM radiation beam and the beam transmitted by the light source (10) reaches to the sample (5) in same axis. To ensure that, a dichroic mirror (4) is used. The dichroic mirror (4) is positioned and selected in such a way that enables passing of the object wave (7) and to reflects the EM radiation beam to the sample (5).

The object wave (7) and the reference wave (8) are received by an image receiving element (1), after merged by the beam splitter (2). The image receiving element (1) is preferably a camera. The beam splitter (2) is preferably positioned angled, more clearly the beam splitter (2) transfers the beam angled way.

Referring to FIGS. 1 and 6; a phase image taken from the image receiving element (1), preferably a hologram, is compared with the target phase. For this comparison, pixelwise subtraction is carried out and if result of subtraction is lower than predetermined value, no action is taken however, if result of subtraction is higher than predetermined value, quantization is carried out for the received phase image. The quantization is designed for different needs. However, success rate is higher, the quantization is carried out by formula of

$${W}_{k} ( x , y ) = \{ \begin{matrix}{2}^{n} − 1 , if {Δ φ}_{k} ( x , y ) > π \\ \frac{( {2}^{n} − 1 ) ⋆ Δ {φ}_{k} ( x , y )}{π} , else\end{matrix} or {W}_{k} ( x , y ) = \{ \begin{matrix}{2}^{n} − 1 , if {Δ φ}_{k} ( x , y ) > a \\ ( {2}^{n} − 1 ) ⋆ {[ \frac{{Δ φ}_{k} ( x , y )}{a} ]}^{m} , else\end{matrix}$$

wherein, Wₖ is the quantized grayscale image to be projected on the spatial light modulator, Δφₖ is the phase difference between the target phase and the present measurement, n is the bit depth of the spatial light modulator, x and y is coordinates of the pixels and k is the iteration number. In the generalized form of the equation, a and m are coefficients.

As a result of the quantization, the new image is created to be used in the spatial light modulator (3). The process is restarted by using this new image and received phase image compare with the target phase and the mentioned process is iterated until the difference is lower than the predetermined value.

Before the comparison, the phase image may be reconstructed. The reconstruction is carried out by finding the difference between phase reconstructed from current phase image and initial reference phase.

After reconstruction, the obtained image may be “unwrapped”.

The comparison is performed by a processing unit with a processing element. Here, the processing unit can also be configured to perform pixel removal and/or reconstruction and/or unwrapping operations.

This method can be employed for other photolithography processes with proper adaption. An example is the 3D structures in silicon for example by using photoinduced chemical etching of silicon. In that case short wave infrared laser and camera is needed for the phase imaging through silicon (where Silicon transparency is higher). In this way, physical channels or vias within a chip can be formed. Another example is the realization of optical waveguides for photonics chips, ultrafast laser induced refractive index change can be utilized here to have these waveguides defined. Besides these any type of 3D structures of crystals or metals may be realized to be part of different chips (for example MEMS chips).

A preferred embodiment of the invention comprises step of,
a) Providing a target phase map (Optical or other element's desired phase map),
b) Turning on EM radiation source (9) for a predefined duration to cause polymerization in all field of view and initialize curing of the photopolymer or photoresist by flood illumination,
c) Turning off the EM radiation source (9) and turning on the laser type light source (10) for digital holographic imaging,
d) Acquire a digital hologram of the sample from the image receiving element (1),
e) Reconstructing the image, hologram, received from the image receiving element (1),
f) Obtaining the phase image,
g) Unwrapping the phase image and calculating the pixelwise difference between the target phase map and unwrapped phase image
h) If the difference is higher than the predetermined value, proceeding next step and if not, ending iteration,
i) Quantize the pixelwise difference. Linearly map the pixelwise difference of values up to a phase of pi to the full bit depth of the spatial light modulator. All phase differences above pi are set to the maximum value of the bit depth.
j) Projecting the quantized image on to the spatial light modulator (3).

An experimental system set up is disclosed below.

### UV Curing Subsystem

The experimental configuration is shown in the FIG. 2. This setup can be divided into 2 parts as UV curing and digital holography, respectively. For UV curing, a light source (10) that has a center wavelength matching with the absorption band of the photopolymer (typically an LED or a laser diode with center wavelength falling between 260 nm and 410 nm) is collimated with the help of a lens (6) such that light overfills the spatial light modulator (3) after collimation. To reduce effect of speckles caused by the laser, a homemade diffuser is mounted on a DC motor to act as a rotating diffuser (11). An additional flat top diffuser (Thorlabs ED1-S20-MD) is placed to ensure homogeneous illumination in the spatial light modulator (3) plane. the spatial light modulator (3) used in this experiment is taken out from a commercial projector (AAXA Technologies P3 Pico Projector) with 1024×600 native resolution and 9.45 μm pixel size (Syndiant Sy12061). Light reflected from the spatial light modulator (3) goes through a polarizing beam splitter (2) (Thorlabs CCM1-PBS251/M) to create contrast. The spatial light modulator (3) plane is imaged on to the sample plane by a unity magnification 4-f configuration through two lenses (6). A mirror (4) in between the two lenses of the 4-f system enables the folding of the optical path. The optical path of the UV curing is folded up by the reflection from a dichroic mirror (4), which reflects the wavelength of the EM radiation source (10) while transmitting wavelength of the light source (10) that is digital holography laser diode. The switching state of 405 nm laser is controlled by a L298N motor driver and Arduino. The fluence of UV illumination in sample plane is 4.23 μW/cm2.

### Digital Holographic Imaging Subsystem

For digital holography measurement, the light coming from a laser diode as the light source (10) with 660 nm center wavelength is collimated and filtered spatially (15) to ensure full spatial coherence. Then this beam divided into two waves by a non-polarizing beam splitter (2) to be used as an object wave (7) and a reference wave (8). The object wave (7) passes through a delay line composed from a knife edge mirror (4) and a right-angle prism (13) to match the temporal phase of reference arm. Then beam from object wave (7) passes through the sample (5) and the dichroic mirror (4). The sample is coincident with the input plane of a 4-f imaging system of two lenses (6) which has unity magnification. With a final non polarizing beam splitter (2), reference wave (8) is directed at image receiving element (1), which is selected as a camera, with a tilted angle and merges with beam coming from object wave (7). This tilt angle enables us to utilize off-axis digital holography methods for determining phase in the sample. (Camera model IDS UI-3080CP). (All 4f configurations a 1-1)

### Phase Reconstruction

For quantification of phase, Fourier filtering is applied to recovery of object wave. To get rid of linear phase modulations, object wave is moved to the center of Fourier plane by division with low frequency terms of spectrum. Measurement of phase change by UV curing is done by finding the difference between phase reconstructed from current hologram and initial reference hologram. The phase image is then unwrapped using a least square phase estimation method. To set a consistent base for each phase image, mean value for phase in a rectangle region which stays out of projected area is calculated and subtracted to obtain final phase images for iterative projection.

### Sample Preparation

Sample (7) is prepared using OrmoComp® positive photoresist which is loaded between two glass slides which is separated by a double-sided tape.

### Projective Transformation

Since iterative method is changing the spatial light modulator (3) input using resulting phase image, it is essential to correctly map the projection to hologram capture. To achieve this, a calibration image is fed to the spatial light modulator (3) and by looking at the resulting phase image, resulting projective transformation is found using MATLAB's fitgeotrans( ) function.

### Projection Calculation

Firstly, the target phase function is given as an image or described mathematically. Secondly, the image receiving element (1) captures the hologram and creates a phase map. After a projective transformation the resulting phase values can be used to create next the spatial light modulator (3) image. For creating of image, the difference between the target phase and current phase is calculated. If the phase difference is bigger than π, the pixel value of 255 for the spatial light modulator (3) is given. Otherwise, a linear mapping is applied to find the corresponding pixel value. This loop continues until the mean phase difference drops below a certain threshold. This threshold value depends on the target phase and decided experimentally.

### Shape Selection

Most photoresists have a nonlinear exposure curve and requires a certain amount of threshold exposure before bonding starts. To decrease the effect of this threshold phenomenon we added a base with π radian phase to ensure even the low value phase targets will be created correctly. A gaussian filter with radius of 10 pixel is applied to the edges of this base phase frame to allow for correct phase unwrapping as it is hard for unwrapping algorithms to detect sudden jumps correctly.

Initial experiments showed that the maximum phase difference we can get with our experimental setup is ~4π. To show capabilities of proposed iterative method, we tried to create 3 different phase plates as square, mayan pyramid and vortex. For square phase plate, the height of square phase region is selected to be 3 π which corresponds to a 2 π phase jump compared to frame. This shape enables us to assess the performance of proposed algorithm for mostly flat surfaces. Mayan pyramid is designed to be look like a square pyramid whose top side is cut off. After that remaining shape is added on to frame as described in the square case. The height of the pyramid is selected to be 3 π which corresponds to a 2 π phase jump compared to frame. This shape allows us to track the behavior of proposed algorithm for constant slope applications.

The last phase plate, vortex is placed on a cut pyramid. The choice for this was to again reduce the effect of phase jumps as this vortex shape has an inherent phase discontinuity at the x axis.

### Standard Deviation Calculation

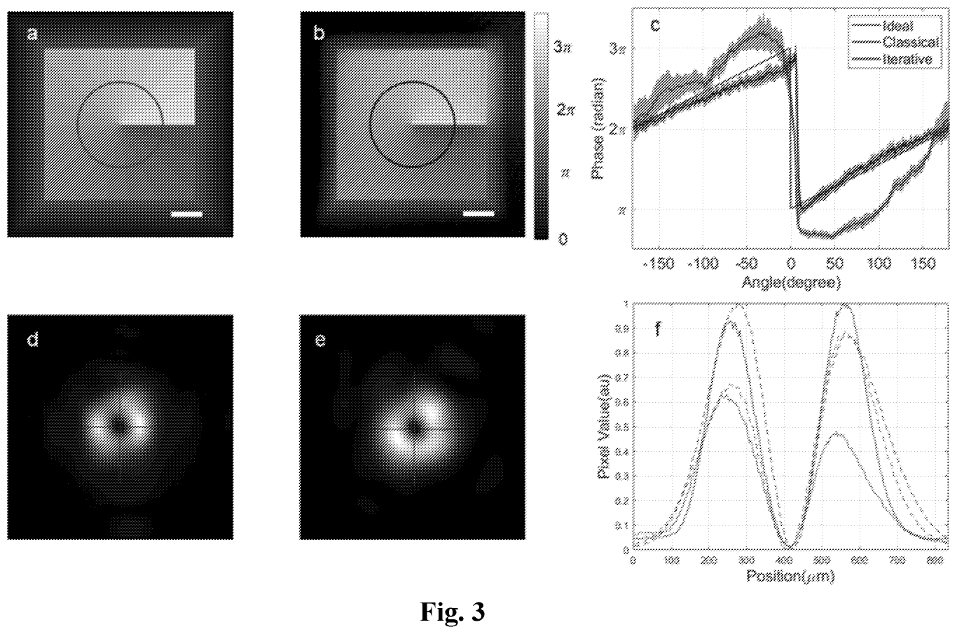

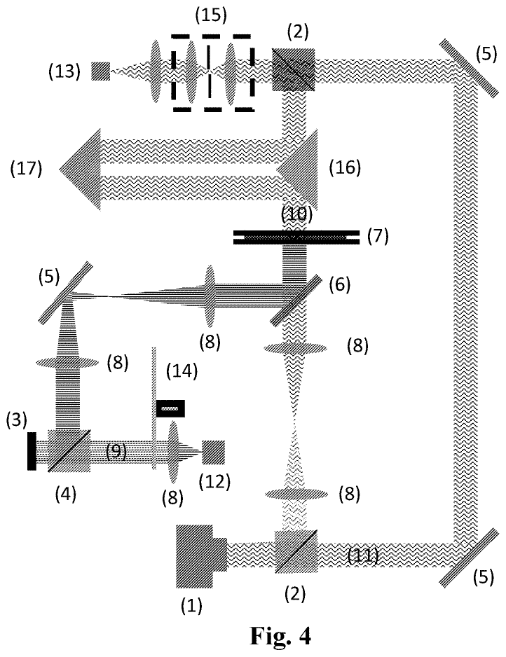

The size of phase images in FIGS. 3-3b and 4-4b are 300×300. The plot in FIG. 3c is constructed using line profiles taken in the direction of arrows and with separation of 5 pixels. Bold line shows the average of these 41line profiles and the highlighted area shows the standard deviation for each point. Scalebar shows a length of 500 μm. Lines shows ideal case, traditional constant and the results for our proposed method.

For the pyramid case shown in FIG. 4-4b, since the flat area is smaller compared to previous case, 21 line profiles are used for the calculation of standard deviation and mean values. The separation for each line is again 5 pixels.

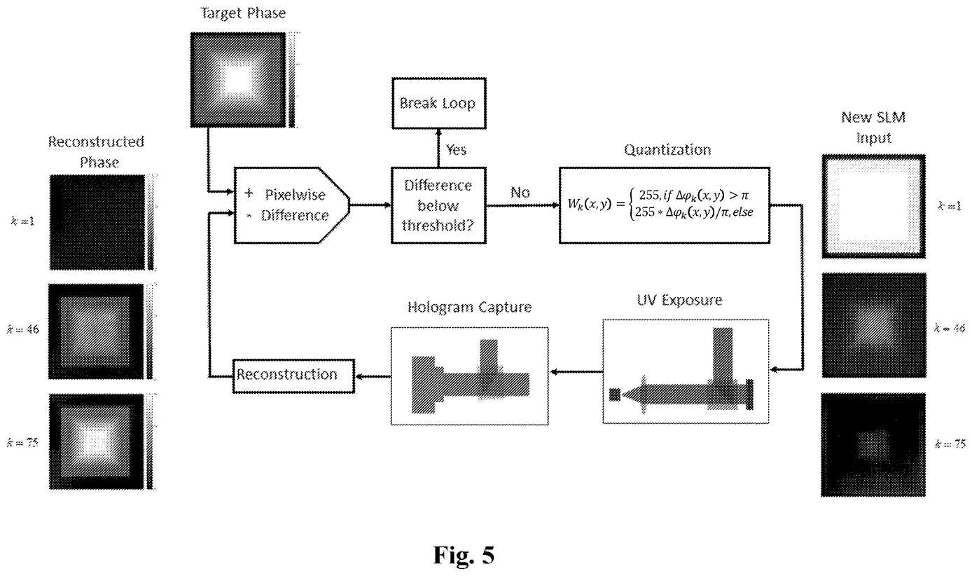

For the vortex case shown in FIG. 5-5b, standard deviation is calculated using line profiles along cocentric rings with different radii. The radius of each ring increases by 5 pixels in each step. For each step, the line profiles are interpolated to an equally spaced angle vector. Once we have the line profiles with same lengths for all radius values, standard deviation and mean is calculated.

### Donut Shape Imaging

For the imaging of donut shape, the written phase plate is placed in front of a collimated laser source. The beam size adjusted such that its diameter is slightly smaller than the size of vortex. Then light which passes through phase plate is focused on camera (Basler acA1440-220 um) with a lens (Thorlabs LB1409-A).

Referring to FIG. 3-3c; For square case, although flatness of top surface is acceptable for classical method, our method improves this by also decreasing the standard deviation across the sample. The mean phase difference for classical and iterative case is 0.62 and 0.29 radian, respectively. We can see that iterative method provides immunity to nonhomogeneous UV illumination as the background and top part has an increasing profile in classical method whereas it stays close to ideal for iterative case.

Referring to FIG. 4-4c; For the pyramid shaped structure, the effect of nonhomogeneous illumination is more apparent. The top of the phase image has a positive slope which signals that the total UV dose in the right side of the phase image is higher compared to left side. The mean phase difference for classical and iterative case is 1.34 and 0.19 radian, respectively. Also, although slope for the sides of pyramids is close to a constant value, they are different from desired slope, and this is the main reason for the increased mean difference. This difference can be corrected by changing the projected pattern for the classical method with the help of a precalibration table. However, running a precalibration process increases costs and requires environmental conditions to stay same for acceptable performance

Referring to FIG. 5-5b; For the last shape we created a 27L vortex phase plate. The performance of proposed method is more pronounced in this phase plate. The experimentally observed donut shaped beam can be seen in FIG. 5. FIG. 5a shows the calculated intensity distribution using the final phase value obtained from digital holographic phase imaging. The mean phase difference for classical and iterative case is 1.57 and 0.46 radian, respectively.

1. A photolithography method comprising the steps of:
providing a target phase;
transmitting a beam from an EM radiation source to a spatial light modulator and the beam reflected from the spatial light modulator to a sample;
dividing a beam provided by a light source into two as an object wave and a reference wave and transmitting the object wave to the sample;
merging and sending the object wave went through the sample and the reference wave to an image receiving element and obtaining a phase image; and
comparing the phase image and the target phase and the quantizing the phase image to create a new image for the spatial light modulator if a difference between the phase image and the target phase is above a predetermined value.

2. The method of claim 1, wherein the comparison of the phase image and the target phase is carried out by pixelwise subtraction.

3. The method of claim 2, wherein the quantization is carried out by a formula of:
$${W}_{k} ( x , y ) = \{ \begin{matrix}{2}^{n} − 1 , if {Δ φ}_{k} ( x , y ) > a \\ ( {2}^{n} − 1 ) ⋆ {[ \frac{Δ {φ}_{k} ( x , y )}{a} ]}^{m} , else\end{matrix} or {W}_{k} ( x , y ) = \{ \begin{matrix}{2}^{n} − 1 , if {Δ φ}_{k} ( x , y ) > π \\ \frac{( {2}^{n} − 1 ) ⋆ {Δ φ}_{k} ( x , y )}{π} , else\end{matrix}$$
wherein, Wₖ is the quantized grayscale image to be projected on the spatial light modulator, Δφₖ is the phase difference between the target phase and the present measurement, n is the bit depth of the spatial light modulator, a and m are coefficients, x and y is coordinates of the pixels and k is the iteration number.

4. The method of claim 1, wherein the reference wave is angularly transmitted to the image receiving element.

5. The method of claim 1, further comprising the step of a reconstructing of the phase image before comparing the phase image and the target phase.

6. The method of claim 5, wherein the reconstruction is carried out by finding the difference between phase reconstructed from current phase image and initial reference phase.

7. The method of claim 5, further comprising the step of unwrapping the phase image obtained by the phase reconstruction.

8. The method of claim 1, wherein the EM radiation beam is applied in discontinuous manner.

9. A photolithography system comprising:
an EM radiation source and a spatial light modulator for receiving a beam from the EM radiation source and reflecting the received beam;
a light source and a beam splitter for dividing a beam provided by the light source into two as an object wave and a reference wave which is transmitted the object wave to the sample; and
a beam splitter for merging the object wave and the reference wave;
an image receiving element for receiving the merged object wave and the reference wave;
a processor unit having
a memory element for storing a target phase and a phase image received by the image receiving element-; and
a processing element is configured to determine the phase image and the target phase and to compare the phase image and the target phase a predetermined value and to quantize the difference for creating a new image and to send the new image to the spatial light modulator.

10. The system of claim 9, wherein the processing element is configured to compare the phase image and the target phase is carried out by pixelwise subtraction.

11. The system of claim 10, wherein the processing element is configured to carry out the quantization by a formula of
$${W}_{k} ( x , y ) = \{ \begin{matrix}{2}^{n} − 1 , if {Δ φ}_{k} ( x , y ) > a \\ ( {2}^{n} − 1 ) ⋆ {[ \frac{Δ {φ}_{k} ( x , y )}{a} ]}^{m} , else\end{matrix} or {W}_{k} ( x , y ) = \{ \begin{matrix}{2}^{n} − 1 , if {Δ φ}_{k} ( x , y ) > π \\ \frac{( {2}^{n} − 1 ) ⋆ {Δ φ}_{k} ( x , y )}{π} , else\end{matrix}$$
wherein, Wₖ is the quantized grayscale image to be projected on the spatial light modulator, Δφₖ is the phase difference between the target phase and the present measurement, n is the bit depth of the spatial light modulator, a and m are coefficients, x and y is coordinates of the pixels and k is the iteration number.

12. The system of claim 9, wherein the beam splitter that merges the object wave and the reference wave is positioned in such a way that angularly transmit the reference wave to the image receiving element.

13. The system of claim 9, wherein the processing element is configured to reconstruct the image received from the imaging element, before comparison.

14. The system of claim 13, wherein the processing element is configured to carry out the reconstruction by finding the difference between phase reconstructed from current phase image and initial reference phase.

15. The system of claim 13, wherein the processing element is configured to unwrap the phase image obtained by the phase reconstruction.
